(19) United States
(12) Patent Application Publication
(10) Pub. No.: US 2009/0301328 A1
(43) Pub. Date: Dec. 10, 2009

(54) MANUFACTURE OF PRINTING CYLINDERS

(75) Inventors: Saden Zahiri, Victoria (AU); Mahnaz Jahedi, Victoria (AU); Christian Antionio, Victoria (AU)

Correspondence Address: BRINKS HOFER GILSON & LIONE, P.O. BOX 10395, CHICAGO, IL, 60610, US

(73) Assignee: Commonwealth Scientific and Industrial Research Organinsation, Campbell (AU)

(21) Appl. No.: 12/158,895

(22) PCT Filed: Dec. 19, 2006
(86) PCT No.: PCT/AU2006/001930

§ 371 Date: Dec. 23, 2008

(30) Foreign Application Priority Data
Dec. 23, 2005 (AU) 2005907288

(51) Int. Cl. B41F 13/10; C23C 16/06

(52) U.S. Cl. 101/375; 427/250

(57) ABSTRACT

The present invention provides a method of manufacturing a printing cylinder, which comprises the application of cold-gas dynamic spraying to provide a printing surface on a substrate cylinder More specifically, the method of the present invention involves cold-gas dynamic spraying of metal particles or metal alloy particles of a predetermined compositions onto a steel, aluminium or polymeric composite substrate cylinder in order to provide a printing layer having suitable surface characteristics capable of being engraved by conventional means such as electronic or laser, high hardness and excellent wear characteristics.

The present invention relates to a method for the manufacture of cylinders (rollers) for the printing industry. More specifically, the present invention relates to the manufacture of cylinders for use in gravure printing processes. The present invention also relates to printing cylinders, including gravure printing cylinders, that have been manufactured in accordance with the method of the present invention.

In gravure printing processes an image is etched on to the surface of a metal plate to produce a recessed image, the recessed image areas are filled with (rapid-drying) ink and the plate rotated in contact with a substrate upon which the image is to be presented. The surface of the cylinder must have certain characteristics that render it suitable for use in the printing process. Thus, the surface must be capable of being engraved with an image, and this is normally done by chemical etching or electromechanical engraving. The surface must also have a good quality (mirror) finish to provide high quality printed images and be hard wearing so that the cylinder has a suitably long working life without deterioration in print image quality.

Conventionally, the cylinders used in gravure printing comprise a steel or aluminium substrate cylinder coated with a layer of copper into which an image may be engraved. Typically the copper layer is provided on the substrate cylinder by electroplating. This can be a relatively slow process, especially as the substrate cylinder needs to be pre-prepared before electroplating can be commenced because copper does not adhere well to steel or aluminium when applied by electroplating. Thus, prior to electroplating, it is conventional to apply a layer of copper cyanide to steel and a layer of zinc and then a layer of nickel to aluminum. Electroplating also tends to consume a lot of water and electricity and involves the use of chemicals that are not environmentally friendly.

In practice, the electroplated copper layer does not have very good wear characteristics and it is therefore also conventional to apply a layer of chrome over the top of it. This is also normally done by electroplating and therefore has the associated drawbacks mentioned above. In the finished cylinder the image is engraved in the copper layer and then a very thin layer of chrome is deposited on the engraved copper surface. Thus, the copper carries the image and the chrome protects it.

Against this background, it would be desirable to provide a process for manufacturing a printing cylinder that does not rely on electroplating technology and that does not suffer the drawbacks described. Specifically, it would be desirable to provide a printing cylinder by a method that is simple to implement and that has relatively high throughput, that does not require pre-preparation of a substrate cylinder, and that produces a print surface that has desirable wear characteristics.

Accordingly, the present invention provides a method of manufacturing a printing cylinder, which comprises the application of cold-gas dynamic spraying to provide a printing surface on a substrate cylinder. More specifically, the method of the present invention involves cold-gas dynamic spraying of metal particles or metal alloy particles of a predetermined composition onto a steel, aluminium or polymeric composite substrate cylinder in order to provide a printing layer having suitable surface characteristics (capable of being engraved by conventional means such as electronic or laser, high hardness and excellent wear characteristics).

Cold-gas dynamic spraying (or cold spraying) is a known process for applying coatings to surfaces. In general terms the process involves feeding (metallic and/or non-metallic) particles into a high pressure gas flow stream which is then passed through a converging/diverging nozzle that causes the gas stream to be accelerated to supersonic velocities. The particles are then directed on to a surface to be coated. The process is carried out at relatively low temperatures, below the melting point of the particles and the substrate to be coated, with a coating being formed as a result of particle impingement on the substrate surface. The fact that the process takes place at relatively low temperature allows thermodynamic, thermal and/or chemical effects on the surface being coated and the particles making up the coating to be reduced or avoided. This means that the original structure and properties of the particles can be preserved without phase transformations etc. that might otherwise be associated with high temperature coating processes such as plasma, HVOF, arc, gas-flame spraying or other thermal spraying processes. The underlying principles, apparatus and methodology of cold-gas dynamic spraying are described, for example, in U.S. Pat. No. 5,302,414.

Herein the expression “printing surface” means the (outer) surface of a printing cylinder that is capable of being engraved to provide a recessed image for use in a (gravure) printing process. In accordance with the present invention, and as will be described, it has been found possible to provide a printing surface on a cylinder substrate as a single, coherent layer having suitable surface characteristics.

In accordance with the present invention it has been found possible to produce a very dense (non-porous) printing surface on a cylinder substrate by suitable choice of the characteristics of particles to be sprayed (type and particle size distribution) and cold spray operating parameters.

An important aspect of the present invention resides in the composition of particles that are applied by the cold spray process. Thus, in one embodiment it has been found advantageous to apply by cold spraying particles of an alloy of copper and zinc. In this embodiment the composition of the powder to be sprayed is typically 88-99 wt % copper and 12-1 wt % zinc. Preferably, the composition comprises 91 wt % copper and 9 wt % zinc.

In this embodiment the average particle size of the individual components is likely to influence the density of the resultant coating. Preferably, the coating is dense and free from defects, micro-voids, and the like, since the presence of such can be detrimental to the quality of the engraving process and hence the printing surface of the cylinder. In the embodiment described, the average particle size is typically from about 15 to about 32 μm with average particle size of about 24 μm. One skilled in the art will be able to determine the optimum particle size or particle size distribution to use based on the morphology and characteristics of the layer that is formed by cold spraying. Metal particles suitable for use in the present invention are commercially available.

In this embodiment the thickness of the deposited layer is typically 300-350 μm. This will typically be reduced by machining to provide a final surface having a thickness of 150-200 μm.

In another embodiment of the invention the printing surface is formed by spraying particles of copper or an alloy of copper and zinc for electronic engraving, and with particles of zinc for laser or electronic engraving. As explained above, the particle size of the metallic particles used for cold spraying will influence the density of the resultant coating, with formation of a consolidated, dense, defect-free coating being desired. In this embodiment, the copper particles will typically have an average particle size of about 10 μm, for example 9 μm, and the zinc particles will have an average particle size of about 10 μm, for example 7 μm. The alloy particles will typically have an average particle size of from about 15 to about 32 μm. Particles useful in this embodiment are commercially available.

In this latter embodiment, the deposited thickness of the copper layer is typically 300-350 μm with the final (machined) thickness typically being 150-200 μm. The thickness of the deposited zinc layer is typically 250-300 μm with the final (machined) thickness being 150-200 μm.

Typically, the printing surface should have a Vickers hardness (VHN) of 225-240 kg/mm². However, copper printing surfaces formed in accordance with the present invention may not exhibit a suitable surface hardness. In an embodiment of the present invention it has been found that suitable hardness values may be achieved by methodology in which metallic particles as described are simultaneously deposited and heat treated through the cold spray process. This was accomplished by manipulating the temperature of the gas stream used in the cold spray process, the rotation speed of the substrate roller during deposition and the speed of the movement of the spray head. All the parameters are adjusted in a way to control the density of dislocations to give the desired hardness.

The substrate cylinders to which the printing surface is applied in accordance with the present invention are of conventional design and dimensions, The cylinder will be formed of steel, aluminium or a polymeric composite. Deposition takes place by positioning the surface of the cylinder adjacent the nozzle from which the metal particles will be accelerated. The distance between the end of the nozzle and the substrate surface (the stand off) may be varied to achieve a coating layer having the desired properties. The cylinder and nozzle will be moved relative to each other in order to coat the outer surface of the cylinder. Thus, the cylinder may be rotated about its longitudinal axis relative to the nozzle and the nozzle moved along the longitudinal axis of the cylinder. The speed with which the cylinder rotates and the nozzle moves along the longitudinal axis will influence the mechanical properties and the thickness of the printing surface that is deposited. The cylinders may be of a form that is otherwise used in the kind of electroplating processes described above.

The operating parameters for the cold spray process may be manipulated in order to achieve a coating that has desirable characteristics (density, surface finish etc). Thus, parameters such as temperature, pressure, stand off (distance between nozzle and substrate surface), powder feed rate and cylinder rotating speed may be adjusted.

The apparatus used for the cold spray process is likely to be of conventional form, and such equipment is commercially available. In general terms the basis of the apparatus used for cold spraying will be as described and illustrated in U.S. Pat. No. 5,302,414.

After manufacture in accordance with the present invention the printing roller are typically machined and polished (e.g. polish master and hand polishing) to provide a suitable surface finish and engraved and used in conventional manner. Alternatively, and depending upon the surface finish, the printing surface may be engraved with an image for printing without machining and polishing. It has been found that the use of cold spray technology in accordance with the present invention provides a print surface having a desirable combination of surface characteristics, as is required in the printing process. In an embodiment, after engraving the printing surface may be chrome plated to provide enhanced wear characteristics.

The present invention also relates to a printing cylinder prepared in accordance with the method of the present invention, and to the use of such a cylinder in a printing process.

Embodiments of the present invention are illustrated in the following non-limiting examples.

These examples use a Kinetic 3000 cold spray system from CGT (Cold Gas Technology GmbH) which has been built based on U.S. Pat. No. 5,302,414. This system consists of a LINSPRAY© gas heater, powder feeder and gun with a standard jet. CGT's long tungsten carbide nozzle was used.

### EXAMPLE 1

A layer of a copper/zinc alloy (91 wt % copper and 9 wt %) was deposited on an aluminium cylinder (diameter 150 mm and length 359 mm). The powder used was a 15-32 micron powder with average particle size 15 micron available from ACL Bearing Company, Australia. The cylinder was rotated at a constant speed of 140 rpm and the spray gun traverse speed was 20 cm/min using the following operating parameters:

| Gas: | Nitrogen | |
|---|---|---|
| Pressure in the heater: | 28.5 | bar |
| Pressure at the jet: | 28.5 | bar |
| Temperature in the heater: | 795° | C. |
| Temperature at the jet: | 685° | C. |
| Spray angle: | 90° | |
| Stand off: | 25 | mm |
| Feeding rate: | 2 | rpm |

| | |
|---|---|
| Proportion of gas going to powder feeder: | 5.5% |

The thickness of the layer was 300-350 μm following by machining to provide a finished layer having a thickness of 150-200 μm.

The average hardness of the coated layer was 280 VHN and an industry trial confined the suitability of the surface for engraving.

### EXAMPLE 2

A layer of a copper was deposited on an aluminium cylinder (diameter 120 mm and length 168 mm) rotated at a constant speed of 140 rpm and spray gun traverse speed was 20 cm/min was used. Oxygen free high conductivity (OFHC) copper powder was obtained from Metal Spray Supplies Australia with average particle size of 15 microns. The following operating parameters were used:

| Gas: | Nitrogen | |
|---|---|---|
| Pressure in the heater: | 25 | bar |
| Pressure at the jet: | 25 | bar |
| Temperature in the heater: | 795° | C. |
| Temperature at the jet: | 700° | C. |
| Spray angle: | 90° | |
| Stand off: | 25 | mm |
| Feeding rate: | 1.8 | rpm |

| | |
|---|---|
| Proportion of gas going to powder feeder: | 5% |

The thickness of the layer was 300-350 μm following by machining to provide a finished layer having a thickness of 150-200 μm.

The average hardness of the coated layer was 190 VHN and requires improvement to be suitable for electronic engraving.

### EXAMPLE 3

A layer of zinc was deposited on an aluminium cylinder (diameter 150 mm and length 359 mm) rotated at a constant speed of 140 rpm and the spray gun traverse speed was 10 cm/min. The powder was obtained from Australian Metal Powders Supplies Pty Ltd (AMPS) and the average particle size was 15 μm. The following operating parameters:

| Gas: | Nitrogen | |
|---|---|---|
| Pressure in the heater: | 20 | bar |
| Pressure at the jet: | 20 | bar |
| Temperature in the heater: | 480° | C. |
| Temperature at the jet: | 385° | C. |
| Spray angle: | 90° | |
| Stand off: | 18 | mm |
| Feeding rate: | 1.8 | rpm |

| | |
|---|---|
| Proportion of gas going to powder feeder: | 16% |

The thickness of the layer was 250-300 μm following by machining to provide a finished layer having a thickness of 150-200 μm.

The average hardness of the coated layer was 108 VHN and the layer was engraved using a laser. An industry trial confirmed the suitability of the surface laser engraving.

Throughout this specification and the claims which follow, unless the context requires otherwise, the word “comprise”, and variations such as “comprises” and “comprising”, will be understood to imply the inclusion of a stated integer or step or group of integers or steps but not the exclusion of any other integer or step or group of integers or steps.

The reference to any prior art in this specification is not, and should not be taken as, an acknowledgment or any form of suggestion that that prior art forms part of the common general knowledge in Australia.

1. A method of manufacturing a printing cylinder, which comprises the application of cold-gas dynamic spraying to provide a printing surface on a substrate cylinder.

2. The method of claim 1, comprising cold-gas dynamic spraying of metal or metal alloy particles onto a substrate cylinder.

3. The method of claim 2, which comprises spraying particles of an alloy of copper and zinc.

4. The method of claim 3, wherein the alloy particles comprise 88-99 wt % copper and 12-1 wt % zinc.

5. The method of claim 4, wherein the alloy particles comprise 91 wt % copper and 9 wt % zinc.

6. The method of claim 3, wherein an average particle size of the particles is from about 15 to about 32 μm.

7. The method of claim, 3 wherein a deposited layer having a thickness of 300-350 μm is formed.

8. The method of claim 2, wherein the printing surface is formed by spraying particles of copper or an alloy of copper and zinc when the printing surface is to be subjected to electronic engraving.

9. The method of claim 8, wherein the copper has an average particle size of about 10 μm.

10. The method of claim 2, wherein the metal is zinc when the printing surface is to be subjected to laser engraving or electronic engraving.

11. The method of claim 10, wherein the zinc has an average particle size of about 7 μm.

12. The method of claim 1, further comprising machining and polishing the printing surface to produce a finished surface and engraving the finished surface with an image for printing.

13. The method of claim 1, further comprising engraving the printing surface with an image for printing.

14. The method of claim 12, further comprising chrome plating the printing surface.

15. A printing cylinder when obtained by the method of claim 1.

16. Use of a printing cylinder when obtained by the method of claim 12 in a printing process.

17. The method of claim 13, further comprising chrome plating the printing surface.
